(19) United States
(12) Patent Application Publication
(10) Pub. No.: US 2018/0127026 A1
(43) Pub. Date: May 10, 2018

(54) STEERING ANGLE DETECTING APPARATUS

(71) Applicant: LS AUTOMOTIVE TECHNOLOGIES CO., LTD., Gyeonggi-do (KR)

(72) Inventors: Tae-Woo KIM, Seoul (KR); Byung-Cheol NA, Gyeonggi-do (KR); Jin-Kyu SHIN, Gyeonggi-do (KR); Tae-Hong JUNG, Seoul (KR); Yeon-Muk CHOI, Gyeonggi-do (KR)

(21) Appl. No.: 15/803,987

(22) Filed: Nov. 6, 2017

(30) Foreign Application Priority Data
Nov. 9, 2016 (KR) 10-2016-0148762

(51) Int. Cl. B62D 15/02; F16H 1/20; G01D 5/16

(52) U.S. Cl. CPC B62D 15/0215; G01R 33/096; G01D 5/16; F16H 1/20

(57) ABSTRACT

Disclosed is a steering angle detecting apparatus, which detects a rotation angle of a steering wheel, and the apparatus includes a main gear configured to rotate in association with a steering shaft connected to the steering wheel, and a plurality of sub gears respectively having a magnet and configured to rotate in engagement with the main gear, wherein a triangle obtained by connecting centers of the main gear and the plurality of sub gears has an area of 334 mm² or above and 528 mm² or below.

### CROSS-REFERENCE TO RELATED APPLICATION

The present application claims priority to Korean Patent Application No. 10-2016-0148762 filed on Nov. 9, 2016 in the Republic of Korea, the disclosures of which are incorporated herein by reference.

### FIELD

The present disclosure relates to a steering angle detecting apparatus, and more particularly, to a steering angle detecting apparatus, which detects a rotation angle of a steering wheel of a vehicle.

### BACKGROUND

A steering device, which is essentially applied to a vehicle, is a device for changing the path and direction of the vehicle according to a driver's request. The steering device basically includes a steering wheel operated by the driver, a steering shaft associated with the steering wheel to transmit the operating force, and a steering angle detecting device mounted to the steering shaft to detect a steering angle of the steering wheel.

Among them, the steering angle detecting device generally employs a magnetic-type device using an anisotropic magneto resistive (AMR) sensor. In the magnetic-type device, a plurality of sub gears respectively having a magnet inserted therein is engaged with and coupled to a main gear connected to a steering shaft, and then the change of magnetic field according to the rotation of the sub gears is measured to calculate the rotation angle of the steering wheel.

FIG. 1 is a schematic view showing a general steering angle detecting device according to the prior art.

As shown in FIG. 1, the general steering angle detecting device according to the prior art includes a single main gear 110 through which a steering shaft (not shown) of a vehicle is coupled so that the single main gear 110 integrally rotates together with the steering shaft, and first and second sub gears 120a, 120b rotating in engagement with the main gear 110. First and second magnets 130a, 130b are respectively coupled to the first and second sub gears 120a, 120b to integrally rotate together with the first and second sub gears 120a, 120b, and first and second sensors 140a, 140b are mounted to outer sides of the first and second sub gears 120a, 120b to detect the change of magnetic field of the first and second magnets 130a, 130b. At this time, the first and second sensors 140a, 140b uses an anisotropic magneto resistive (AMR) sensor.

Thus, if a driver turns the steering wheel (not shown) so that the steering shaft rotates, the main gear 110 rotates, and accordingly the first and second sub gears 120a, 120b and the first and second magnets 130a, 130b rotate. The change of magnetic field caused by the rotation of the first and second magnets 130a, 130b is detected by the first and second sensors 140a, 140b, and each detection signal is transmitted to a calculation unit 150 so that a rotation angle of the steering wheel is calculated using a separate algorithm.

### SUMMARY

### Technical Problem

The inventors of the present disclosure have found that in the magnetic-type steering angle detecting device as described above, the arrangement of a main gear and two sub gears gives a great influence on the performance.

Thus, the present disclosure is directed to providing a steering angle detecting apparatus, which may reduce an error rate in the measurement of a rotation angle by optimizing the arrangement of a main gear and two sub gears.

### Technical Solution

In one aspect of the present disclosure, there is provided a steering angle detecting apparatus, which detects a rotation angle of a steering wheel, the apparatus comprising: a main gear configured to rotate in association with a steering shaft connected to the steering wheel; and a plurality of sub gears respectively having a magnet and configured to rotate in engagement with the main gear, wherein a triangle obtained by connecting centers of the main gear and the plurality of sub gears has an area of 334 mm² or above and 528 mm² or below.

Preferably, a distance between the centers of the main gear and any one sub gear of the plurality of sub gears may be 27 mm or above and 38 mm or below, and a distance between the centers of the main gear and another sub gear of the plurality of sub gears may be 27.5 mm or above and 38.5 mm or below.

More preferably, a distance between the centers of the plurality of sub gears may be 25 mm or above and 35 mm or below.

### Advantageous Effects

According to an embodiment, an error rate in the measurement of a rotation angle of a steering wheel is reduced by optimizing the arrangement of a main gear and two sub gears.

The steering angle detecting apparatus according to an embodiment may enhance the accuracy of a vehicle driver in operating a steering wheel.

### BRIEF DESCRIPTION OF DRAWINGS

FIG. 1 is a schematic view showing a general steering angle detecting device according to the prior art.

FIG. 2 is a diagram for illustrating an engagement structure of a main gear and two sub gears, employed at a steering angle detecting apparatus according to an embodiment.

FIG. 3 is a diagram showing a distance between centers of two engaged gears according to an embodiment.

FIG. 4 is a diagram showing a test environment of the steering angle detecting apparatus according to an embodiment.

FIG. 5 is a graph of Table 2.

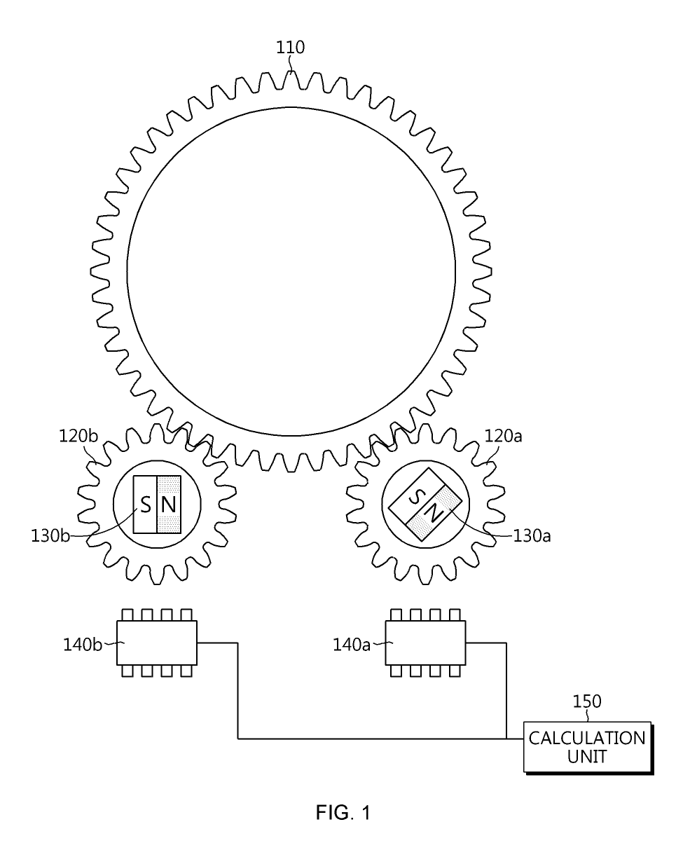

### DETAILED DESCRIPTION

The above objects, features and advantages of the present disclosure will become apparent from the following descriptions of the embodiments with reference to the accompanying drawings, from which it will be deemed that a person having ordinary skill can easily practice the technical features of the present disclosure. Also, any explanation of the prior art known to relate to the present disclosure may be omitted if it is regarded to render the subject matter of the present disclosure vague. Hereinafter, an embodiment of the present disclosure will be described in detail with reference to the accompanying drawings.

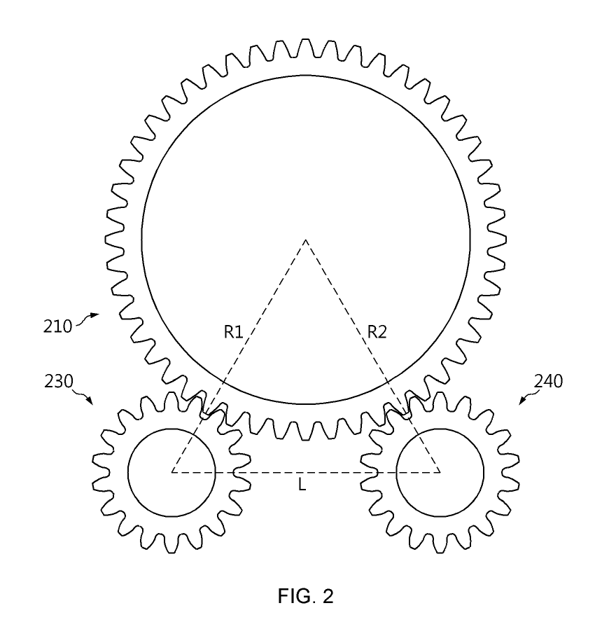

FIG. 2 is a diagram for illustrating an engagement structure of a main gear 210 and two sub gears 230, 240, employed at a steering angle detecting apparatus according to an embodiment. In an embodiment, two sub gears 230, 240 are symmetrically disposed to have a stable detection function. A magnet is installed at the inside of each sub gear 230, 240. In addition, a magnetic sensor is installed at an outer side of each sub gear 230, 240, preferably with a predetermined distance from the magnet of each sub gear 230, 240 in a vertical direction, to face the magnet. If the main gear 210 rotates according to the rotation of the steering shaft, two sub gears 230, 240 engaged with the main gear 210 also rotate, and at this time, the change of magnetic field caused by the magnets of two sub gears 230, 240 is detected by the magnetic sensor.

Generally, as two gears rotating in engagement with each other have a larger size, the backlash increases and thus the contact ratio is greatly deteriorated. The backlash is a gap created between surfaces of two teeth when two gears are engaged. Thus, if the main gear 210 and two sub gears 230, 240 of the steering angle detecting apparatus have a greater size, a measurement error rate of the steering angle increases due to the deterioration of the contact ratio. The inventors of the present disclosure have endeavored to reduce the size of the main gear 210 and two sub gears 230, 240 in order to decrease the backlash and improve the contact ratio. However, it has been found that the measurement error rate of the steering angle is still not reduced to a meaningful level. The inventors of the present disclosure though that if the size of the main gear 210 and two sub gears 230, 240 is reduced, the distance between two sub gears 230, 240 decreases to generate interference of magnetic fields between the magnets installed at the sub gears 230, 240, which causes an error in the measurement value of the steering angle. Thus, the inventors have attempted to increase the distance between the sub gears 230, 240 while maintaining the size of the main gear 210 and the sub gears 230, 240, but it was found that the measurement error rate of the rotation angle was not reduced in proportion thereto. After many efforts, the inventors found that the size of the gears 210, 230, 240 and the distance between two sub gears 230, 240 having magnets comprehensively affect the error rate. In other words, the inventors found that a triangle obtained by connecting center points of the gears 210, 230, 240 gives a direct effect on the error rate.

Referring to FIG. 2, an area A of the triangle obtained by connecting the center points of the gears 210, 230, 240 is calculated using Equation 1 below.

$$A = \sqrt{s ( s - R 1 ) ( s - R 2 ) ( s - L )} , where s = \frac{R 1 + R 2 + L}{2} \qquad Equation 1$$

R1 represents a distance between the centers of the main gear 210 and the sub gear 230, R2 represents a distance between the centers of the main gear 210 and the sub gear 240, and L represents a distance between the centers of two sub gear 230, 240.

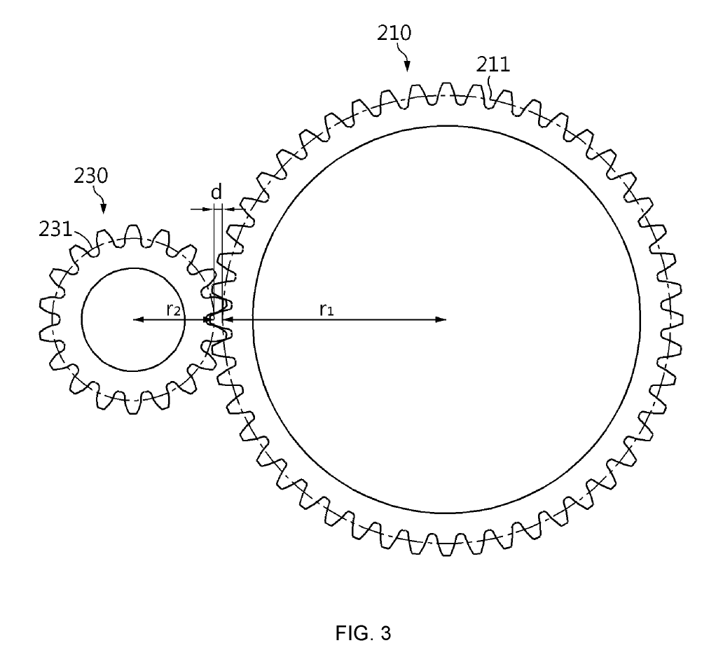

FIG. 3 is a diagram showing a distance between centers of two engaged gears according to an embodiment and depicts a distance between the centers of the main gear 210 and the sub gear 230. Referring to FIG. 3, the distance between the centers of the main gear 210 and the sub gear 230 is a sum of a radius r₁ of a pitch circle 211 of the main gear 210, a radius r₂ of a pitch circle 231 of the sub gear 230, and a shortest distance d between two pitch circles 211, 231. A distance between the centers of the main gear 210 and the sub gear 240 is also calculated in the same way.

If the area A of the triangle obtained by connecting the center points of three gears 210, 230, 240 of steering angle detecting apparatus as described above is 334 mm² or above and 528 mm² or below, the measurement error rate of the steering angle is reduced to a meaningful level. At this time, the distance R1 between the centers of the main gear 210 and the sub gear 230 is preferably 27 mm or above and 38 mm or below. In addition, the distance R2 between the centers of the main gear 210 and the sub gear 240 is preferably 27.5 mm or above and 38.5 mm or below. In addition, the distance L between the centers of the sub gear 230 and the sub gear 240 is preferably 25 mm or above and 35 mm or below.

Hereinafter, the result of the performance experiment of the steering angle detecting apparatus according to the area A of the triangle obtained by connecting the center points of three gears 210, 230, 240 will be described.

Preparation of a Sample

Ten steering angle detecting apparatuses were prepared so that the area A of the triangle obtained by connecting the center points of three gears 210, 230, 240 is different from each other. The distance between the centers of the gears 210, 230, 240 of ten steering angle detecting apparatuses and the area A of the triangle obtained by connecting the center points of the gears 210, 230, 240 are as in Table 1 below.

TABLE 1

| | R1 (mm) | R2 (mm) | L (mm) | A (mm²) |
|---|---|---|---|---|
| Comparative Example 1 | 24 | 24.5 | 24 | 253 |
| Comparative Example 2 | 25 | 25.5 | 27 | 288 |
| Comparative Example 3 | 26 | 26.5 | 32 | 333 |
| Example 1 | 27 | 27.5 | 29 | 334 |
| Example 2 | 28 | 28.5 | 35 | 388 |
| Example 3 | 37 | 37.5 | 25 | 439 |
| Example 4 | 38 | 38.5 | 30 | 528 |
| Comparative Example 4 | 39 | 39.5 | 29 | 529 |
| Comparative Example 5 | 40 | 40.5 | 36 | 648 |
| Comparative Example 6 | 41 | 41.5 | 38 | 696 |

Seeing Table 1, the area A of the triangle increases from the first row to the last row. In Comparative Examples 1 to 3, the area A of the triangle obtained by connecting the center points of three gears 210, 230, 240 is lower than 334 mm². In Examples 1 to 4, the area A of the triangle obtained by connecting the center points of three gears 210, 230, 240 is 334 mm² or above and 528 mm² or below. In Comparative Examples 4 to 6, the area A of the triangle obtained by connecting the center points of three gears 210, 230, 240 is greater than 528 mm².

Measurement of Performance

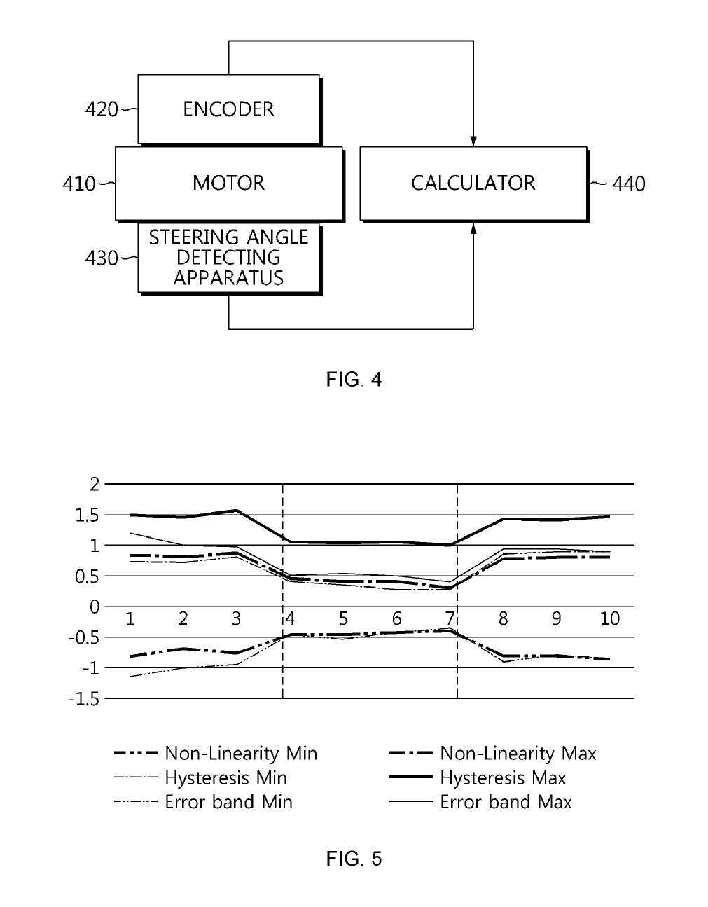

The performance was measured using a SAS (Steering Angle Sensor) Performance Tester. FIG. 4 is a diagram showing a test environment of the steering angle detecting apparatus according to an embodiment. As shown in FIG. 4, a steering angle detecting apparatus 430 is coupled to one end of a rotary shaft of a motor 410, and an encoder 420 is coupled to the other end of the rotary shaft. Here the rotary shaft of the motor 410 serves as a steering shaft of a vehicle, and the rotating speed is 100 rpm. A calculator 440 calculates three parameters by using an output value of the steering angle detecting apparatus 430 and an output value received from the encoder 420. Three parameters are non-linearity, hysteresis, and an error band. The calculator 440 receives the output value for 4 to 5 seconds at 10 ms intervals from each steering angle detecting apparatus and calculates a maximum value (max) and a minimum value (min) of three parameters.

The error band means a difference between an actual rotation angle of the rotary shaft and a rotation angle measured by the steering angle detecting apparatus 430. In an embodiment, the error band means a difference between the output value of the encoder 420 and the output value of the steering angle detecting apparatus 430.

The non-linearity is a value representing how linearly the rotation angle is measured by the steering angle detecting apparatus 430. The non-linearity is a difference between a trend line of values measured by the steering angle detecting apparatus 430 and each measured value.

The hysteresis means a maximum error range which may occur at one point, namely at a specific rotation angle.

If three parameters are closer to 0, it is determined that the product reliability is high.

In detail, three parameters of ten steering angle detecting apparatuses as in Table 1 are as in Table 2 below. FIG. 5 is a graph of Table 2.

TABLE 2

| | Non-linearity | | Hysteresis | | Error band | |
|---|---|---|---|---|---|---|
| | Min | Max | Min | Max | Min | Max |
| Comparative Example 1 | −0.81 | 0.82 | 0.73 | 1.5 | −1.13 | 1.2 |
| Comparative Example 2 | −0.71 | 0.81 | 0.71 | 1.46 | −0.99 | 1 |
| Comparative Example 3 | −0.78 | 0.86 | 0.79 | 1.56 | −0.95 | 0.97 |
| Example 1 | −0.47 | 0.45 | 0.39 | 1.06 | −0.47 | 0.51 |
| Example 2 | −0.45 | 0.4 | 0.35 | 1.01 | −0.5 | 0.52 |
| Example 3 | −0.43 | 0.41 | 0.28 | 1.05 | −0.43 | 0.47 |
| Example 4 | −0.38 | 0.31 | 0.3 | 1 | −0.33 | 0.4 |
| Comparative Example 4 | −0.81 | 0.77 | 0.86 | 1.41 | −0.89 | 0.9 |
| Comparative Example 5 | −0.83 | 0.78 | 0.88 | 1.42 | −0.82 | 0.92 |
| Comparative Example 6 | −0.85 | 0.8 | 0.9 | 1.46 | −0.85 | 0.89 |

Referring to Tables 1 and 2 as well as FIG. 5, in Comparative Examples 1 to 6, the non-linearity has a minimum value (Min) of −0.71 or below and a maximum value (Max) of 0.77 or above. Meanwhile, in Examples 1 to 4, the non-linearity has a minimum value (Min) of −0.47 or above and a maximum value (Max) of 0.45 or below, which is closer to 0 in comparison to the comparative examples. In addition, if Comparative Examples 1 to 3 are compared with Example 1, when the area A becomes 334 mm² or above, the minimum value (Min) and the maximum value (Max) of the non-linearity become closer to 0 abruptly. In addition if Comparative Examples 4 to 6 are compared with Example 4, when the area A exceeds 528 mm², the minimum value (Min) and the maximum value (Max) of the non-linearity become farther from 0 abruptly.

In relation to the hysteresis, in Comparative Examples 1 to 6, the hysteresis has a minimum value (Min) of 0.71 or above and a maximum value (Max) of 1.41 or above. Meanwhile, in Examples 1 to 4, the hysteresis has a minimum value (Min) of 0.39 or below and a maximum value (Max) of 1.06 or below, which is closer to 0 in comparison to the comparative examples. In addition, if Comparative Examples 1 to 3 are compared with Example 1, when the area A becomes 334 mm² or above, the minimum value (Min) and the maximum value (Max) of the hysteresis become closer to 0 abruptly. In addition if Comparative Examples 4 to 6 are compared with Example 4, when the area A exceeds 528 mm², the minimum value (Min) and the maximum value (Max) of the hysteresis become farther from 0 abruptly.

In relation to the error band, in Comparative Examples 1 to 6, the error band has a minimum value (Min) of −0.82 or below and a maximum value (Max) of 0.89 or above. Meanwhile, in Examples 1 to 4, the error band has a minimum value (Min) of −0.5 or above and a maximum value (Max) of 0.52 or below, which is closer to 0 in comparison to the comparative examples. In addition, if Comparative Examples 1 to 3 are compared with Example 1, when the area A becomes 334 mm² or above, the minimum value (Min) and the maximum value (Max) of the error band become closer to 0 abruptly. In addition if Comparative Examples 4 to 6 are compared with Example 4, when the area A exceeds 528 mm², the minimum value (Min) and the maximum value (Max) of the error band become farther from 0 abruptly.

Thus, it may be understood that an optimal mode, namely a best mode, is obtained when the area A of the triangle obtained by connecting the center points of three gears 210, 230, 240 of the steering angle detecting apparatus is 334 mm² or above and 528 mm² or below. At this time, seeing Table 1, the distance R1 between the centers of the main gear 210 and the sub gear 230 is preferably 27 mm or above and 38 mm or below. In addition, the distance R2 between the centers of the main gear 210 and the sub gear 240 is preferably 27.5 mm or above and 38.5 mm or below. In addition, the distance L between the centers of the sub gear 230 and the sub gear 240 is preferably 25 mm or above and 35 mm or below.

While the present disclosure includes many features, such features should not be construed as limiting the scope of the present disclosure or the claims. Further, features described in respective embodiments of the present disclosure may be implemented in combination in a single embodiment. On the contrary, a variety of features described in a single embodiment of the present disclosure may be implemented in various embodiments, singly or in proper combination.

It should be understood by those skilled in the art that many adaptations, modifications and changes may be made to the present disclosure without departing from the technical aspects of the present disclosure, and the present disclosure described hereinabove is not limited by the disclosed embodiments and the accompanying drawings.

What is claimed is:

1. A steering angle detecting apparatus, which detects a rotation angle of a steering wheel, the apparatus comprising:
a main gear configured to rotate in association with a steering shaft connected to the steering wheel; and
a plurality of sub gears respectively having a magnet and configured to rotate in engagement with the main gear,
wherein a triangle obtained by connecting centers of the main gear and the plurality of sub gears has an area of 334 mm² or above and 528 mm² or below.

2. The steering angle detecting apparatus according to claim 1,
wherein a distance between the centers of the main gear and any one sub gear of the plurality of sub gears is 27 mm or above and 38 mm or below, and
wherein a distance between the centers of the main gear and another sub gear of the plurality of sub gears is 27.5 mm or above and 38.5 mm or below.

3. The steering angle detecting apparatus according to claim 2,
wherein a distance between the centers of the plurality of sub gears is 25 mm or above and 35 mm or below.
